(19) United States
(12) Patent Application Publication
(10) Pub. No.: US 2026/0013167 A1
(43) Pub. Date: Jan. 8, 2026

(54) HIGH-VOLTAGE RESISTANT ENHANCEMENT-MODE GAN DEVICE EASY TO INTEGRATE

(71) Applicant: SOUTHEAST UNIVERSITY, Nanjing (CN)

(72) Inventors: Weifeng SUN, Nanjing (CN); Siyang LIU, Nanjing (CN); Sheng LI, Nanjing (CN); Weixiong MAO, Nanjing (CN); Weihao LU, Nanjing (CN); Longxing SHI, Nanjing (CN)

(73) Assignee: SOUTHEAST UNIVERSITY, Nanjing (CN)

(21) Appl. No.: 19/123,078

(22) PCT Filed: Sep. 24, 2024
(86) PCT No.: PCT/CN2024/120546

§ 371 Date: Apr. 22, 2025

(30) Foreign Application Priority Data
Feb. 23, 2024 (CN) 202410202657.X

(51) Int. Cl. H10D 30/47; H10D 62/824

(52) U.S. Cl. CPC H10D 30/471; H10D 62/824

(57) ABSTRACT

A high-voltage resistant enhancement-mode GaN device with enhanced integration is provided. A nucleating layer, a buffer layer, and a GaN layer are sequentially stacked on a silicon substrate. A p-GaN region and an AlGaN barrier layer are formed on the GaN layer, with a first n-GaN region embedded in the p-GaN region. A first metal electrode is connected to the first n-GaN region, while a second metal electrode, serving as a gate, is placed on a first SiO₂ oxide layer above the p-GaN region. A fourth metal electrode acts as a drain on the AlGaN barrier layer. A second n-GaN region divides the AlGaN barrier into two sections, with a third metal electrode on a second SiO₂ oxide layer connected to the first metal electrode as a source. The second n-GaN region and the third metal electrode mitigate edge effects.

### CROSS-REFERENCE TO THE RELATED APPLICATIONS

This application is the national phase entry of International Application No. PCT/CN2024/120546, filed on Sep. 24, 2024, which is based upon and claims priority to Chinese Patent Application No. 202410202657.X, filed on Feb. 23, 2024, the entire contents of which are incorporated herein by reference.

### TECHNICAL FIELD

The invention belongs to the field of power semiconductor devices, and particularly relates to a high-voltage resistant enhancement-mode GaN device easy to integrate.

### BACKGROUND

GaN, belonging to the category of third-generation semiconductors, is gradually known by people because of its large energy gap, high breakdown voltage and high electron saturation velocity. In GaN-based transistors, high electron mobility transistors (HEMTs) are gradually applied to various circuits because of the high mobility achieved by two-dimensional electron gas (2DEG) generated by their polarization effect.

In the power electronics technology, enhancement-mode (normally-off) devices are in an off state in case of a zero bias, such that the reliability of the devices is greatly improved. Correspondingly, depletion-mode devices are still in an on state in case of a zero bias of the gate of the devices, such that the reliability of power devices is greatly affected. In the field of power devices, the voltage resistance is one of the important factors for evaluating the performance of the power devices. Therefore, it is necessary to design a high-voltage resistant device.

The breakdown voltage of GaN HEMTs is related to the gate-drain distance of devices. When the gate-drain distance is small, the voltage resistance of devices may be improved by increasing the gate-drain distance. However, with the increase in the gate-drain distance, the increase rate of the devices becomes smaller gradually, that is, the breakdown voltage of the devices satisfies the marginal diminishing effect. The voltage resistance of existing GaN HEMTs is improved by changing the position of an electric field peak between a gate and a drain of devices. A more uniform electric field distribution between the gate and the drain of the devices may avoid a large-peak electric field that easily leads to breakdowns of the devices, thus improving the voltage resistance of the devices. For example, in Patent Publication No.CN111403480A, a T-type gate field plate and a p-GaN structure are adopted, a p-GaN region is introduced to exert an influence on the electric field distribution of the gate, and an electric field peak is transferred below the gate field plate under the action of the T-type gate field plate, such that the voltage resistance of a device is improved. For example, in Patent Publication No.CN113035935B, an AlGaN barrier layer with the thickness changing gradually from the gate to the drain is introduced to change the concentration of 2DEG to alleviate the electric field peak so as to ensure the high voltage resistance of a device. However, all the above devices are structures within a constant gate-drain distance, and when the gate-drain distance increases, they will enter the range of the marginal diminishing effect prematurely, so the improvement on the voltage resistance of the devices is limited. Therefore, it is of great significance to design an enhancement-mode device that is easy to design and capable of delaying the marginal diminishing effect of the voltage resistance and has a high voltage-resistance threshold.

### SUMMARY

The objective of the invention is to design a high-voltage resistant enhancement-mode GaN device easy to integrate, the marginal diminishing effect of the voltage resistance of which is mitigated.

The invention adopts the following technical solution:
A high-voltage resistant enhancement-mode GaN device easy to integrate includes: a second silicon substrate, wherein a nucleating layer, a buffer layer and a GaN layer are arranged on the second silicon substrate from bottom to top, a p-GaN region and an AlGaN barrier layer are arranged on the GaN layer, a first n-GaN region is arranged in the p-GaN region, a first metal electrode is connected to the first n-GaN region, a first SiO₂ oxide layer is arranged on the p-GaN region and has two ends extending to the first n-GaN region and a first AlGaN barrier layer respectively, a second metal electrode is arranged on the first SiO₂ oxide layer and used as a gate of the device, a fourth metal electrode is arranged on the AlGaN barrier layer and used as a drain of the device, a second n-GaN region and a second SiO₂ oxide layer are arranged on the AlGaN barrier layer, a third metal electrode is arranged on the second SiO₂ oxide layer, the second n-GaN region extends deep to the GaN layer and divides the AlGaN barrier layer into the first AlGaN barrier layer and a second AlGaN barrier layer, the second SiO₂ oxide layer and the third metal electrode are located between the second n-GaN region and the fourth metal electrode, and the third metal electrode is connected to the first metal electrode and used as a source of the device.

Beneficial effects: Compared with the prior art, the invention has the following advantages:
(1) The second n-GaN region and the third metal electrode of the invention mitigate the marginal diminishing effect of the voltage resistance of the device and increase the voltage-resistance threshold of the device. Specifically, by introducing the second n-GaN region and the third metal electrode, when a voltage is applied to the device, a depletion region starts to expand from the second metal electrode; when the depletion region expands to the second n-GaN region, the depletion rate is decreased by the second n-GaN region, and the induced electromotive force in the second n-GaN region increases gradually; the induced electromotive force between the second n-GaN region and the third metal electrode increases the energy band of the second AlGaN barrier layer, and when the energy band of the second AlGaN barrier layer is higher than the Fermi level of the GaN layer, a 2DEG trench region generated by polarization is depleted, and the depletion layer starts to expand again from the second n-GaN region. For example, referring to FIG. 1, the depletion layer starts to expand again from the second n-GaN region towards the right side, such that the marginal diminishing effect of the voltage resistance of the device is mitigated, the voltage-resistance threshold of the device is increased, and the voltage resistance of the device is further improved.
(2) The enhancement mode of the device is realized. The first n-GaN region, the first p-GaN region and the first AlGaN barrier layer of the GaN device are etched to weaken the polarization effect formed by AlGaN and GaN below the second metal electrode and an etched region of the first SiO₂ oxide layer, such that the energy band of GaN is increased; when the energy band is increased to the Fermi level of the GaN layer, 2DEG in a trench region will be depleted, such that the enhancement mode of a grooved portion is realized. In addition, when the gate voltage of the device drops from a threshold, because the width of a non-grooved portion is small, the depletion region below the grooved portion will expand horizontally, thus realizing the enhancement mode of the whole device. The enhancement-mode device is free of the problem of failures caused by overshoots of depletion-mode devices, such that the reliability of the designed device is improved.
(3) The high-voltage resistant enhancement-mode GaN device is easy to integrate. With the continuous development of technology, power devices are developing towards integration gradually. The device provided by the invention is integrated on an SOI substrate, such that the high-voltage resistant enhancement-mode GaN device may be integrated with other devices, thus improving the integration level of the device.
(4) The operating temperature of the device is increased. The insulating SiO₂ layer may hinder the migration of high-temperature electrons from the first silicon substrate to the buffer layer, such that the operating temperature of the device is increased, and the device may operate at an ultrahigh temperature.
(5) Crosstalk between devices is eliminated. When multiple devices work together, the devices may be mutually affected due to the connection of substrates. In the invention, the insulating SiO₂ layer in the structure may separate the designed device from other devices, thus eliminating substrate crosstalk in application of multiple devices to an integrated circuit.
(6) Dynamic resistance degradation is alleviated. In the operating process of GaN devices, because the substrate is not connected to the source, a trap of a voltage activation buffer layer of the substrate will be caused, leading to dynamic resistance degradation of the GaN devices. In the invention, holes are punched in the first metal electrode to the second silicon substrate to alleviate dynamic resistance degradation caused by substrate floating.

### BRIEF DESCRIPTION OF THE DRAWINGS

To better clarify the technical solutions in the embodiments of the invention or the prior art, drawings used for describing the embodiments of the invention or the prior art are briefly introduced below. Obviously, the drawings in the following description merely illustrate some embodiments of the invention, and those ordinarily skilled in the art may obtain other drawings according to the following ones without creative labor.

FIG. 1 illustrates a structural diagram of a high-voltage resistant enhancement-mode GaN device easy to integrate according to the invention;

FIGS. 2A-2B illustrate sectional views of L1 and L2 along an X-axis in the structural diagram according to the invention, wherein FIG. 2A illustrates the sectional view of L1 along the X-axis, and FIG. 2B illustrates the sectional view of L2 along the X-axis;

FIGS. 3A-3D illustrate sectional view of L3, L4, L5 and L6 along a Y-axis in the structural diagram according to the invention, wherein FIG. 3A illustrates the sectional view of L3 along the Y-axis, FIG. 3B illustrates the sectional view of L4 along the Y-axis, FIG. 3C illustrates the sectional view of L5 along the Y-axis, and FIG. 3D illustrates the sectional view of L6 along the Y-axis;

FIGS. 4A-4C show a flow of the expansion of a depletion layer in the process of realizing the enhancement mode of the whole device according to the invention.

### DETAILED DESCRIPTION OF THE EMBODIMENTS

To better clarify the objectives, contents and advantages of the invention, the specific implementation of the invention is described in further detail below in conjunction with accompanying drawings and embodiments. The following embodiments are merely used for more clearly explaining the technical solutions of the invention rather than limiting the protection scope of the invention.

A high-voltage resistant enhancement-mode GaN device easy to integrate includes: a second silicon substrate 3, wherein a nucleating layer 4, a buffer layer 5 and a GaN layer 6 are arranged on the second silicon substrate 3 from bottom to top, a p-GaN region 7 and an AlGaN barrier layer are arranged on the GaN layer 6, a first n-GaN region 8 is arranged in the p-GaN region 7, a first metal electrode 14 is connected to the first n-GaN region 8, a first SiO₂ oxide layer 12 is arranged on the p-GaN region 7 and has two ends extending to the first n-GaN region 8 and a first AlGaN barrier layer 10 respectively, a second metal electrode 15 is arranged on the first SiO₂ oxide layer 12 and used as a gate of the device, a fourth metal electrode 17 is arranged on the AlGaN barrier layer and used as a drain of the device, a second n-GaN region 9 and a second SiO₂ oxide layer 13 are arranged on the AlGaN barrier layer, a third metal electrode 16 is arranged on the second SiO₂ oxide layer 13, the second n-GaN region 9 extends deep to the GaN layer 6 and divides the AlGaN barrier layer into the first AlGaN barrier layer 10 and a second AlGaN barrier layer 11, the second SiO₂ oxide layer 13 and the third metal electrode 16 are located between the second n-GaN region 9 and the fourth metal electrode 17, and the third metal electrode 16 is connected to the first metal electrode 14 and used as a source of the device.

In this embodiment:
An insulating SiO₂ layer 2 is arranged below the second silicon substrate 3, and a first silicon substrate 1 is arranged below the insulating SiO₂ layer 2; a groove is formed in the p-GaN region 7, the first n-GaN region 8 and the first AlGaN barrier layer 10 below the first SiO₂ oxide layer 12, and part of the first SiO₂ oxide layer 12 sinks into the groove.

Each of the first metal electrode, the second metal electrode, the third metal electrode and the fourth metal electrode is formed by a single elemental metal layer. As another embodiment, each of the first metal electrode, the second metal electrode, the third metal electrode and the fourth metal electrode is formed by multiple elemental metal layers. An elemental metal is one of Au, Ti, Ni, W, Pt and Al.

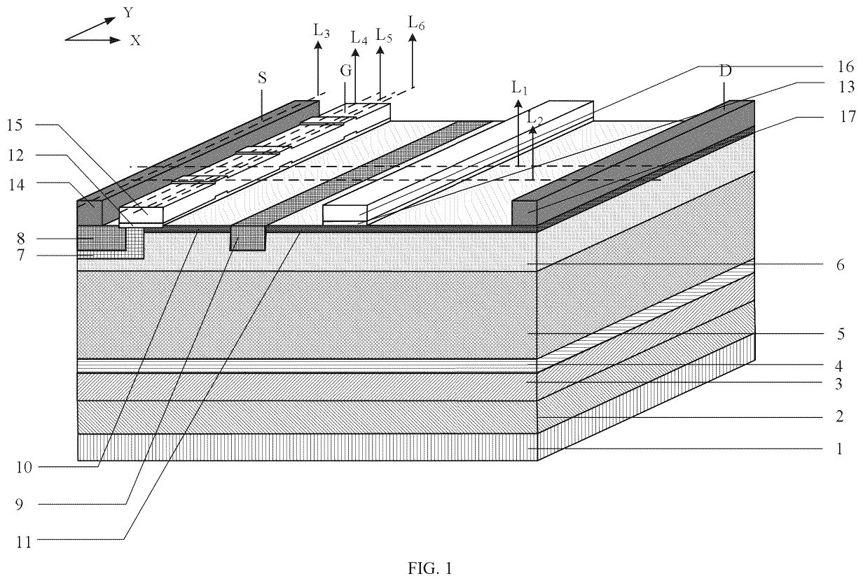

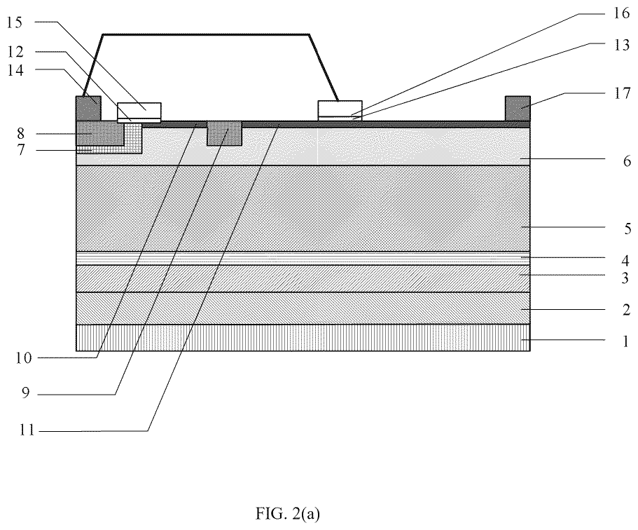

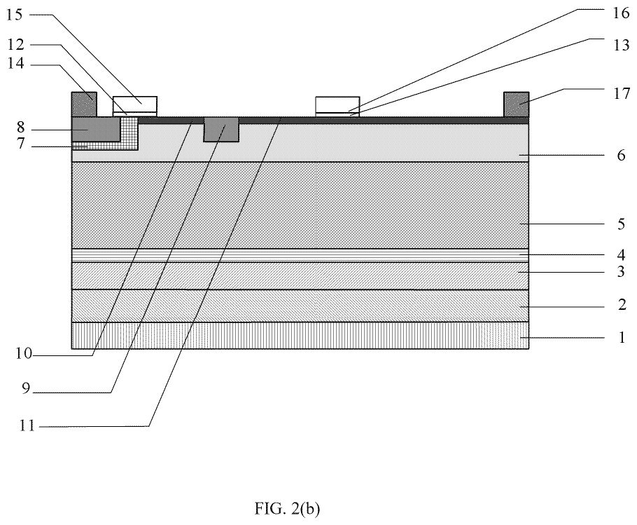

The specific implementation of the invention is described in further detail below with reference to the accompanying drawings:
As shown in FIG. 1, a high-voltage resistant enhancement-mode GaN device easy to integrate designed in the invention includes a first silicon substrate 1, an insulating SiO₂ layer 2, a second silicon substrate 3, a nucleating layer 4, a buffer layer 5, a GaN layer 6, a p-GaN region 7, a first n-GaN region 8, a second n-GaN region 9, a first AlGaN barrier layer 10, a second AlGaN barrier layer 11, a first SiO₂ oxide layer 12, a second SiO₂ oxide layer 13, a first metal electrode 14, a second metal electrode 15, a third metal electrode 16 and a fourth metal electrode 17; the nucleating layer is used for mitigating a lattice mismatch between the second silicon substrate 3 and the buffer layer 5.

Wherein, in the above structure, the first metal electrode 14 is connected to the third metal electrode 16 and used as a source of the high-voltage resistant enhancement-mode GaN device. Wherein, the connection between the first metal electrode 14 and the third metal electrode 16 may be internal metal connection or external wire connection (in FIG. 2A, the two metal electrodes are connected by means of an external wire). The second metal electrode 15 is used as a gate of the high-voltage resistant enhancement-mode GaN device, and the fourth metal electrode 17 is used as a drain of the high-voltage resistant enhancement-mode GaN device.

The high-voltage resistant enhancement-mode GaN device easy to integrate is characterized in that each of the first metal electrode 14, the second metal electrode 15, the third metal electrode 16 and the fourth metal electrode 17 is formed by a single elemental metal layer or multiple elemental metal layers, and an elemental metal includes, but not limited to, Au, Ti, Ni, W, Pt and Al.

When a zero voltage or negative voltage is applied to the gate of the high-voltage resistant enhancement-mode GaN device, the p-GaN region 7 and a 2DEG trench region below the second metal electrode 15 are closed. When a high voltage is applied to the drain of the device, a depletion region starts to expand from the boundary of the p-GaN region 7 and the GaN layer 6; when the depletion region expands to the second n-GaN region 9, the depletion rate is decreased, and the induced electromotive force in the second n-GaN region 9 increases gradually; the induced electromotive force between the second n-GaN region 9 and the third metal electrode 16 increases the energy band of the second AlGaN barrier layer 11 and the energy band of the GaN layer 6 below, and when the energy band of the GaN layer 6 is higher than the Fermi level, the 2DEG trench region generated by polarization is depleted, at this moment, there is no carrier that migrates directionally in the GaN layer 6 on the right side of the second n-GaN region 9, and the depletion layer starts to expand again from the right side of the second n-GaN region 9. Therefore, the introduction of the second n-GaN region 9 and the third metal electrode mitigates the marginal diminishing effect of the voltage resistance of the device and improve the voltage resistance of the device.

A groove is etched in the p-GaN region 7, the first n-GaN region 8 and the first AlGaN barrier layer 10 below the first SiO₂ oxide layer 12, and part of the first SiO₂ oxide layer 12 sinks into the groove; then, the first SiO₂ oxide layer and the second metal electrode 15 are deposited, and the polarization effect formed by the grooved portion of the first AlGaN barrier layer 10 and the GaN layer 6 is weakened, such that the energy band of the GaN layer 6 is increased relatively; when the depth of the groove is large enough to increase the energy band of the GaN layer 6 to be above the Fermi level, 2DEG in the trench region formed by the GaN layer 6 and the first AlGaN barrier layer 10 will be depleted, such that no carrier will flow through the device when no bias voltage is applied to the gate of the device, that is, the enhancement mode of the grooved portion of the device is realized. In addition, when the gate voltage of the device drops from a threshold, because the width of the non-grooved portion is small, the depletion region below the grooved portion will expand horizontally, thus realizing the enhancement mode of the whole device.

In addition, according to the high-voltage resistant GaN device, when a positive voltage applied to the gate of the device reaches a voltage threshold of the device, a region, close to the gate, in the p-GaN region 7 turns from the p type to the n type, electrons from the first n-GaN region 8 pass through the p-GaN region 7 to reach the second n-GaN region 9, and at this moment, a 2DEG trench formed by the GaN layer 6 and the first AlGaN barrier layer 10 further improves the current capacity of the device; a potential difference between the second n-GaN region 9 and the third metal electrode 16 is zero, and a 2DEG trench formed by the GaN layer 6 and the second AlGaN barrier layer is completely opened, and the electrons flow to the fourth metal electrode 17 to form a complete current path. From the above description, the current path is: the second metal electrode 15→the first n-GaN region 8→the p-GaN region 7→the 2DEG trench region formed by the first AlGaN barrier layer and the GaN layer→the second n-GaN region 9→the 2DEG trench region formed by the second AlGaN barrier layer 11 and the GaN layer 6→the fourth metal electrode 17.

The insulating SiO₂ layer 2 may hinder the migration of electrons at a high temperature from the first silicon substrate 1 to the second silicon substrate 3, such that the device may operate at an ultrahigh temperature; substrate crosstalk in application of multiple devices to an integrated circuit may be eliminated; the device is effectively isolated from other devices, the parasitic capacitance is reduced, the switching loss is reduced, and the switching frequency is increased.

For the high-voltage resistant enhancement-mode GaN device, holes are punched in the first metal electrode 14 to the second silicon substrate 3 to alleviate dynamic resistance degradation caused by substrate floating.

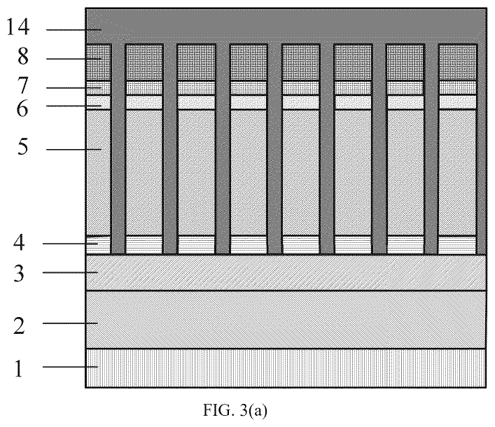

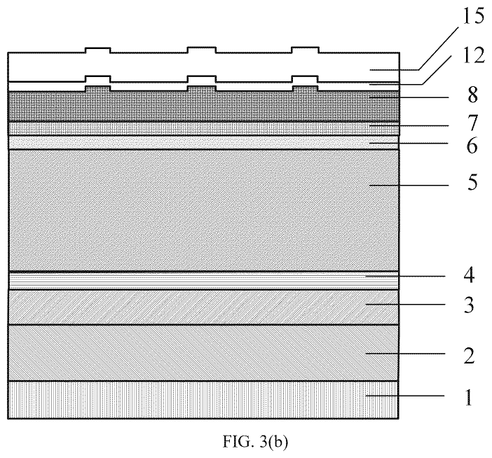

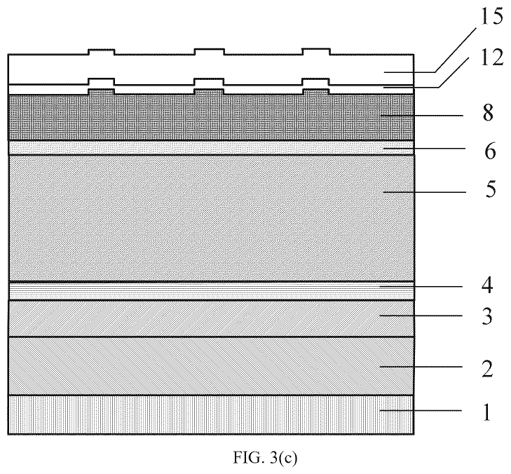

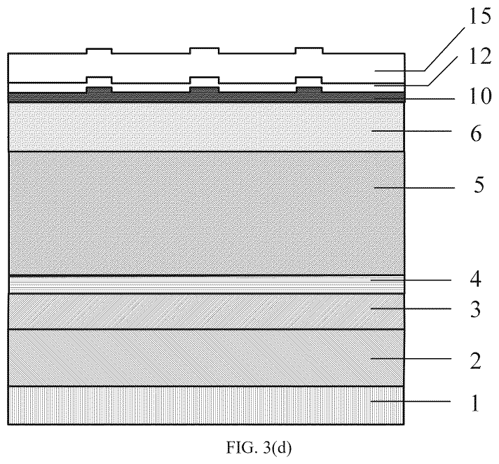

FIGS. 2A, 2B and 3B illustrate the sectional views of the device along L1, L2 and LA, wherein L1 and L4 depict the sectional views of an etched region of the first AlGaN barrier layer of the device in different etching directions, and L2 depicts the sectional view of a non-etched region of the first AlGaN barrier layer of the device. It can be known that the first AlGaN barrier layer is etched to realize the enhancement mode of the device, and the non-etch region is reserved to improve the current capacity of the device to reduce the on-resistance of the device.

As shown in FIG. 3A which illustrates the sectional view of the device along L3. It can be known that holes are punched in the first metal electrode at intervals to allow the source of the device to be directly connected to the second silicon substrate of the device, such that when the drain of the device suffers from a high voltage, the second silicon substrate of the device will not generate redundant carriers, that are captured by electrons or hole traps, due to substrate floating. which may otherwise generate a current collapse effect (dynamic resistance degradation) when the device is turned on.

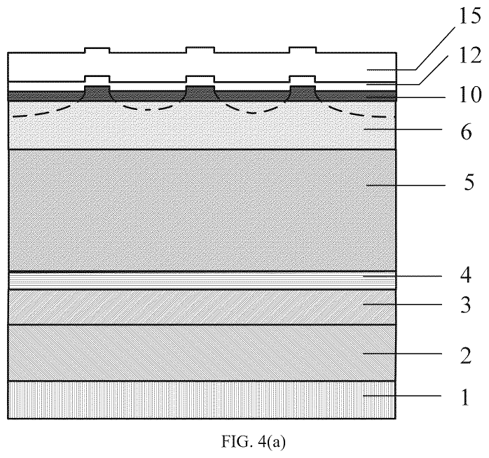

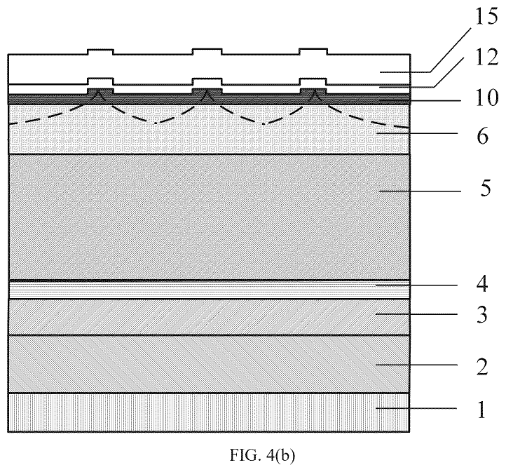

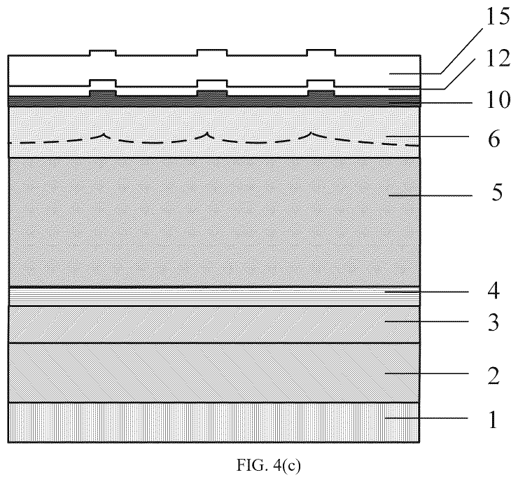

As shown in FIG. 4A, when a voltage is applied to the device, the depletion layer expands from the AlGaN layer to the GaN layer in all directions rather than one direction, including the Y-direction. As shown in FIG. 4B, because the distance of the non-grooved region is much smaller than the distance of the grooved region in the Y-direction, the depletion layer of the device will reach the state shown in FIG. 4B, and at this moment, the device will reach a critical state; by increasing the drain voltage of the device, the depletion layer of the device will further expand to reach the state shown in FIG. 4C, and at this moment, the depletion layer of the device will form an area, that is, the grooved region will deplete the non-grooved region, such that the enhancement mode of the whole device is realized.

The above embodiments are merely preferred ones of the invention and are not intended to limit the scope of the invention in any way. Any improvements and modifications made by those ordinarily skilled in the art without departing from the technical principle of the invention should also fall within the protection scope of the invention.

What is claimed is:

1. A high-voltage resistant enhancement-mode GaN device easy to integrate, comprising: a second silicon substrate, wherein a nucleating layer, a buffer layer and a GaN layer are arranged on the second silicon substrate from bottom to top, a p-GaN region and an AlGaN barrier layer are arranged on the GaN layer, a first n-GaN region is arranged in the p-GaN region, a first metal electrode is connected to the first n-GaN region, a first SiO₂ oxide layer is arranged on the p-GaN region and has two ends extending to the first n-GaN region and a first AlGaN barrier layer respectively, a second metal electrode is arranged on the first SiO₂ oxide layer and used as a gate of the device, a fourth metal electrode is arranged on the AlGaN barrier layer and used as a drain of the device, a second n-GaN region and a second SiO₂ oxide layer are arranged on the AlGaN barrier layer, a third metal electrode is arranged on the second SiO₂ oxide layer, the second n-GaN region extends deep to the GaN layer and divides the AlGaN barrier layer into the first AlGaN barrier layer and a second AlGaN barrier layer, the second SiO₂ oxide layer and the third metal electrode are located between the second n-GaN region and the fourth metal electrode, and the third metal electrode is connected to the first metal electrode and used as a source of the device.

2. The high-voltage resistant enhancement-mode GaN device easy to integrate according to claim 1, wherein an insulating SiO₂ layer is arranged below the second silicon substrate, and a first silicon substrate is arranged below the insulating SiO₂ layer.

3. The high-voltage resistant enhancement-mode GaN device easy to integrate according to claim 1, wherein a groove is formed in the p-GaN region, the first n-GaN region and the first AlGaN barrier layer below the first SiO₂ oxide layer, and part of the first SiO₂ oxide layer sinks into the groove.

4. The high-voltage resistant enhancement-mode GaN device easy to integrate according to claim 3, wherein each of the first metal electrode, the second metal electrode, the third metal electrode and the fourth metal electrode is formed by a single elemental metal layer.

5. The high-voltage resistant enhancement-mode GaN device easy to integrate according to claim 3, wherein each of the first metal electrode, the second metal electrode, the third metal electrode and the fourth metal electrode is formed by multiple elemental metal layers.

6. The high-voltage resistant enhancement-mode GaN device easy to integrate according to claim 4, wherein an elemental metal is one of Au, Ti, Ni, W, Pt and Al.

7. The high-voltage resistant enhancement-mode GaN device easy to integrate according to claim 2, wherein a groove is formed in the p-GaN region, the first n-GaN region and the first AlGaN barrier layer below the first SiO₂ oxide layer, and part of the first SiO₂ oxide layer sinks into the groove.

8. The high-voltage resistant enhancement-mode GaN device easy to integrate according to claim 5, wherein an elemental metal is one of Au, Ti, Ni, W, Pt and Al.

9. The high-voltage resistant enhancement-mode GaN device easy to integrate according to claim 7, wherein each of the first metal electrode, the second metal electrode, the third metal electrode and the fourth metal electrode is formed by a single elemental metal layer.

10. The high-voltage resistant enhancement-mode GaN device easy to integrate according to claim 7, wherein each of the first metal electrode, the second metal electrode, the third metal electrode and the fourth metal electrode is formed by multiple elemental metal layers.

11. The high-voltage resistant enhancement-mode GaN device easy to integrate according to claim 9, wherein an elemental metal is one of Au, Ti, Ni, W, Pt and Al.

12. The high-voltage resistant enhancement-mode GaN device easy to integrate according to claim 10, wherein an elemental metal is one of Au, Ti, Ni, W, Pt and Al.
